(19) United States
(12) Patent Application Publication
(10) Pub. No.: US 2026/0331344 A1
(43) Pub. Date: Oct. 22, 2026

(54) ACTUATOR, LITHOGRAPHY APPARATUS, AND ARTICLE MANUFACTURING METHOD

(71) Applicant: CANON KABUSHIKI KAISHA, Tokyo (JP)

(72) Inventors: YUICHI FUJITA, Tochigi (JP); HAYATO HOSHINO, Tochigi (JP)

(21) Appl. No.: 19/649,710

(22) Filed: Apr. 16, 2026

(30) Foreign Application Priority Data
Apr. 22, 2025 (JP) 2025-070798

(51) Int. Cl. H01F 7/08; G03F 7/00; H05K 7/20

(52) U.S. Cl. CPC H01F 7/081; G03F 7/70758; G03F 7/70875; H05K 7/2039

(57) ABSTRACT

An actuator includes a mover and a stator, wherein one of the mover and the stator includes a yoke, a plurality of coils arrayed around the yoke along an axial direction of the yoke, and a cooling unit arranged inside the yoke, and the cooling unit includes a first member having a plurality of grooves extending along the axial direction of the yoke, and a second member arranged to face the plurality of grooves.

### BACKGROUND

### Field of the Technology

The present disclosure relates to an actuator, a lithography apparatus, and an article manufacturing method.

### Description of the Related Art

In a lithography apparatus for manufacturing an article such as a semiconductor device, a machine tool, a moving body such as a railroad car, a positioning apparatus, or the like, an actuator is used. For example, Japanese Patent Laid-Open No. 2005-94902 describes an actuator that includes a stator structure including a stationary coil annularly wound about a driving shaft and a mover including a movable magnet that generates thrust in the direction of the driving shaft in interaction with the stationary coil. In this actuator, a cooling medium passage is provided in the stator structure.

If thrust generated by an actuator is increased, heat generated by a coil increases, and thus a structure for efficiently recovering the heat is required.

### SUMMARY

The present disclosure provides a technique advantageous in efficiently recovering heat generated by a coil.

One of aspects of the present disclosure is directed to an actuator comprising a mover and a stator. One of the mover and the stator may include a yoke, a plurality of coils arrayed around the yoke along an axial direction of the yoke, and a cooling unit arranged inside the yoke. The cooling unit may include a first member having a plurality of grooves extending along the axial direction of the yoke, and a second member arranged to face the plurality of grooves.

Features of the present disclosure will become apparent from the following description of embodiments with reference to the attached drawings. The following description of embodiments is described by way of example.

### BRIEF DESCRIPTION OF THE DRAWINGS

The accompanying drawings, which are incorporated in and constitute a part of the specification, illustrate embodiments of the present disclosure, and together with the description, serve to explain the principles of the embodiments.

FIG. 1 is a perspective view showing the configuration of an actuator according to the first embodiment;

FIG. 2A is a sectional view (a section A of FIG. 1) showing the configuration of the actuator according to the first embodiment;

FIG. 2B is a sectional view (a section B of FIG. 1) showing the configuration of the actuator according to the first embodiment;

FIG. 3A is a perspective view showing the configuration of a component forming a cooling unit of the actuator according to the first embodiment;

FIG. 3B is a sectional view showing an example of the configuration of the component forming the cooling unit of the actuator shown in FIG. 3A;

FIG. 3C is a sectional view showing another example of the configuration of the component forming the cooling unit of the actuator shown in FIG. 3A;

FIGS. 4A and 4B are sectional views each showing the configuration of an actuator according to the second embodiment;

FIG. 5 is a sectional view showing the configuration of a component forming a cooling unit of the actuator according to the second embodiment; and

FIG. 6 is a schematic view showing an example of a lithography apparatus.

### DESCRIPTION OF THE EMBODIMENTS

Hereinafter, embodiments will be described in detail with reference to the attached drawings. Note, the following embodiments are not intended to limit the scope of the claims. Multiple features are described in the embodiments, but it is not the case that all such features are required, and multiple such features may be combined as appropriate. Furthermore, in the attached drawings, the same reference numerals are given to the same or similar configurations, and redundant description thereof is omitted.

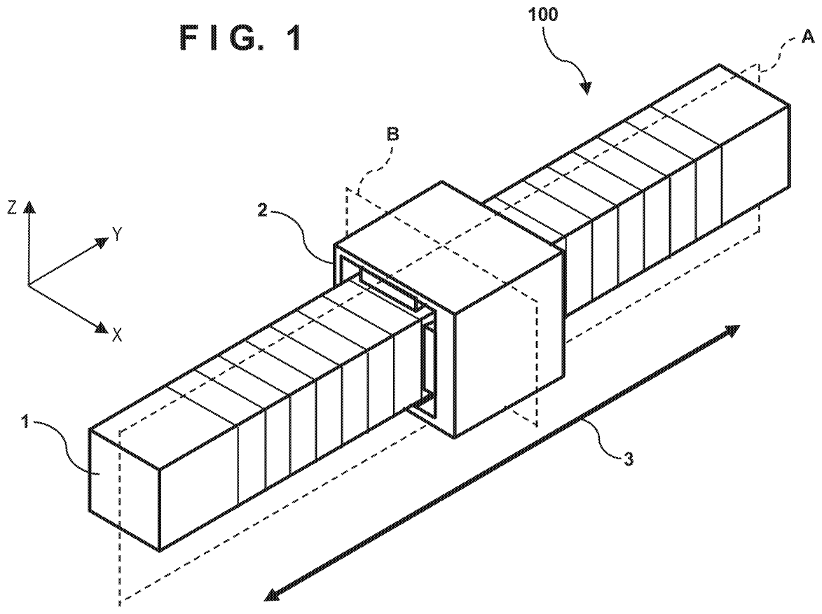

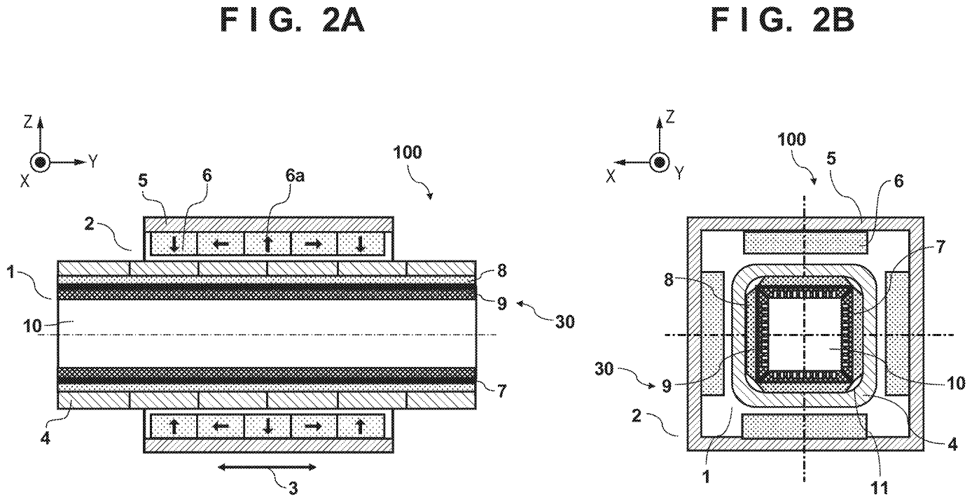

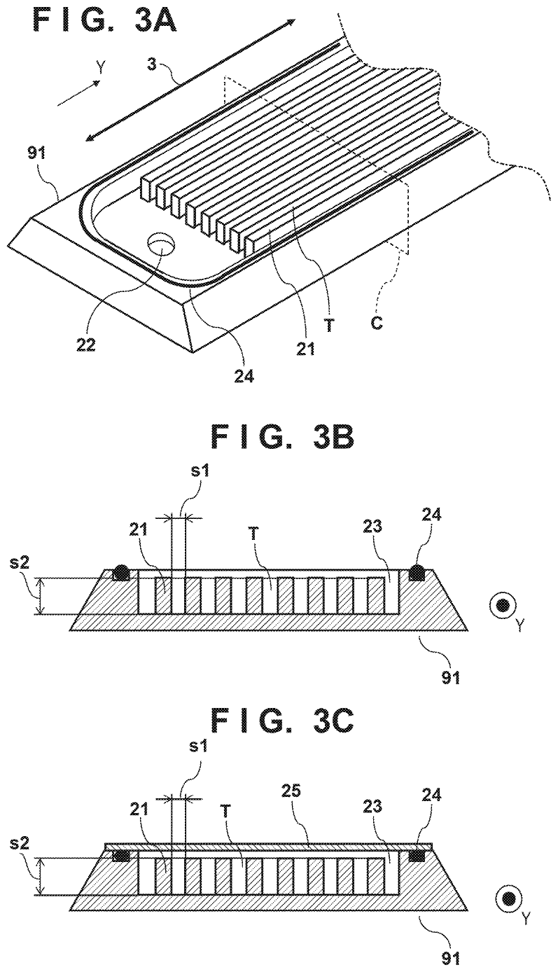

An actuator 100 according to the first embodiment will be described with reference to FIGS. 1, 2A, 2B, and 3A to 3C. FIG. 1 is a perspective view of the actuator 100. FIG. 2A is a sectional view showing a section A (a section parallel to the Y-Z plane) in FIG. 1, and FIG. 2B is a sectional view showing a section B (a section parallel to the X-Z plane) in FIG. 1. FIG. 3A is a perspective view showing one component (a component 91 forming a first member 9 of a cooling unit 30) of the actuator 100. The actuator 100 can include a first element 1 as one of a mover and a stator and a second element 2 as the other of the mover and the stator. An expression “stator and mover” is a relative expression. A stator has a small absolute moving amount at the time of the operation of the actuator 100, and a mover has a large absolute moving amount. That is, if, at the time of the operation of the actuator 100, the absolute moving amount of the second element 2 is larger than that of the first element 1, the second element 2 serves as a mover and the first element 1 serves as a stator. To the contrary, if, at the time of the operation of the actuator 100, the absolute moving amount of the first element 1 is larger than that of the second element 2, the first element 1 serves as a mover and the second element 2 serves as a stator. The actuator 100 can be formed as a linear motor, as exemplified in FIGS. 1, 2A, 2B, and 3A to 3C.

The first element 1 as one of the mover and the stator can include a yoke 8, a plurality of coils 4 arrayed around the yoke 8 along the axial direction (Y-axis direction) of the yoke 8, and the tubular-shaped or rod-shaped cooling unit 30 arranged inside the yoke 8. The axial direction (Y-axis direction) of the yoke 8 is parallel to a relative moving direction 3 of the first element 1 and the second element 2. The cooling unit 30 can include the first member 9 having a plurality of grooves T extending along the axial direction (Y-axis direction) of the yoke 8, and a support member 10 or a facing member 25 serving as a second member arranged to face the plurality of grooves T. If no facing member 25 is provided, the support member 10 can function as the second member. If the facing member 25 is provided, the facing member 25 can function as the second member. The plurality of grooves T define a passage 23 through which a refrigerant flows. The first member 9 is arranged outside the support member 10 or the facing member 25 serving as the second member.

The second element 2 as the other of the mover and the stator can be arranged to surround the first element 1 in a section (a section parallel to the X-Z plane) orthogonal to the moving direction 3. From another viewpoint, the second element 2 has an opening extending through in the moving direction 3 in the section (the section parallel to the X-Z plane) orthogonal to the moving direction 3, and the first element 1 is arranged through the opening. The second element 2 can include a plurality of magnets 6 arrayed so that the magnetization direction changes along the moving direction 3, and a housing 5 that supports the plurality of magnets 6. The plurality of magnets 6 can be arrayed to form, for example, a Halbach array that generates a one-cycle substantially sine wave magnetic field. Note that reference numeral 6a denotes a direction of a magnetic pole. The plurality of magnets 6 can be arranged respectively on four surfaces forming the inner side surfaces of the housing 5. The plurality of magnets 6 can be fixed to the housing 5 by adhesion or bolting. A yoke (not shown) may be arranged between the housing 5 and the plurality of magnets 6.

The first element 1 may include the support member 10 that supports the first member 9. In the first element 1, the plurality of coils 4 can be arranged at equal intervals along the moving direction 3. Each coil 4 can have an annular shape surrounding the support member 10. The plurality of coils 4 can be arranged to form coil lines of a plurality of phases (for example, two phases). The plurality of coils 4 can be driven by a sine wave driving method so that a current and a magnetic flux are orthogonal. To reduce heat generated by the plurality of coils 4, it is preferable to supply a current only to coils facing the plurality of magnets 6 among the plurality of coils 4. To use the magnetic flux generated by the coils 4 efficiently as a driving force, the gap between the coils 4 and the magnets 6 can be made as small as possible.

The plurality of coils 4 and the yoke 8 arranged inside the coils 4 can be adhered by an adhesive layer 7. Alternatively, an insulating member may be arranged between the plurality of coils 4 and the yoke 8 arranged inside the coils 4. In this case, the insulating member can be adhered to the plurality of coils 4 and the yoke 8 by an adhesive layer. If each coil 4 has a rectangular shape with rounded corners in a section (a section parallel to the X-Z plane) orthogonal to the moving direction 3, a gap 11 can be formed inside the corner of the coil 4. In this case, the gap 11 is preferably filled with the same material as that of the yoke 8, an adhesive, or a heat transfer member.

The first member 9 can be formed by a combination of a plurality of components 91, and some of the plurality of grooves T can be formed in each of the plurality of components 91. The first member 9 can be formed by, for example, a combination of four components 91. Each component 91 can have a plate shape, as exemplified in FIG. 3A. In an example, each component 91 can be fixed to the inner side surface of the yoke 8 by an adhesive, and can be fixed to the support member 10 by bolting or an adhesive. The adhesive used for it has a high thermal conductivity, and has adhesion and heat resistance to a temperature rise of the coils 4 at the time of the operation of the actuator 100.

FIG. 3B exemplifies a configuration in which the support member 10 faces the first member 9 (the plurality of components 91) and the first member 9 (the plurality of components 91) and the support member 10 define the refrigerant passage 23. FIG. 3C exemplifies a configuration in which the facing members 25 face the first member 9 (the plurality of components 91) and the first member 9 (the plurality of components 91) and the facing members 25 define the refrigerant passage 23. In the example shown in FIG. 3C, the facing members 25 respectively facing the plurality of components 91 can be supported by the support member 10.

The first member 9 and the components 91 forming it can include a plurality of fins 21 arranged to define the plurality of grooves T. Each fin 21 extends along the axial direction (Y-axis direction) of the yoke 8. An interval s1 (the width of the groove T) between the plurality of fins 21 is preferably smaller than a height s2 of each of the plurality of fins 21. This configuration is advantageous in efficiently transferring, to a refrigerant, heat transferred from the coils 4 to the fins 21. In a section (a section parallel to the X-Z plane) orthogonal to the axial direction of the yoke 8, the plurality of fins 21 may protrude toward the inside of the cooling unit 30. This configuration is advantageous in transferring heat generated by the coils 4 to the fins 21. The plurality of fins 21 can be arranged not to contact the support member 10 or the facing members 25 serving as the second member. Each component 91 forming the first member 9 can include a refrigerant inlet 22 for taking a refrigerant and a refrigerant outlet (not shown) for discharging the refrigerant. The refrigerant may contain both a gas and a liquid or may contain only a gas or only a liquid.

In the example shown in FIG. 3B, an O-ring 24 can be arranged between the support member 10 and each of the plurality of components 91 forming the first member 9. In the example shown in FIG. 3C, the O-ring 24 can be arranged between each of the plurality of components 91 forming the first member 9 and its corresponding facing member 25. In the example shown in FIGS. 3A and 3B and the example shown in FIGS. 3A and 3C, assume that the first member 9 is formed by the four components 91. However, the number of components 91 is not limited to four. For example, two or more components 91 may form one surface of the first member 9 or one member may form two or more surfaces of the first member 9.

In the example shown in FIG. 3B, the first member 9 (the plurality of components 91) and the support member 10 can be made of the same material having a high thermal conductivity, for example, a material containing copper. Alternatively, the first member 9 (the plurality of components 91) and the support member 10 can be made of different metals. In a case where the first member 9 (the plurality of components 91) and the support member 10 are made of different metals, a region where the first member 9 (the plurality of components 91) and the support member 10 contact the refrigerant can be covered with a plating film or the like to suppress corrosion due to contact between dissimilar metals. In an example, the first member 9 (the plurality of components 91) can be made of a material superior in thermal conductivity, for example, a material containing copper, and the support member 10 can be made of a material superior in lightness, for example, a material containing aluminum.

In the example shown in FIG. 3C, the first member 9 (the plurality of components 91) and the plurality of facing members 25 can be made of the same material having a high thermal conductivity, for example, a material containing copper. Alternatively, the first member 9 (the plurality of components 91) and the plurality of facing members 25 can be made of different metals. In a case where the first member 9 (the plurality of components 91) and the plurality of facing members 25 are made of different metals, a region where the first member 9 (the plurality of components 91) and the plurality of facing members 25 contact the refrigerant can be covered to suppress corrosion due to contact between dissimilar metals. In an example, the first member 9 (the plurality of components 91) can be made of a material superior in thermal conductivity, for example, a material containing copper, and the plurality of facing members 25 can be made of a material superior in lightness, for example, a material containing aluminum.

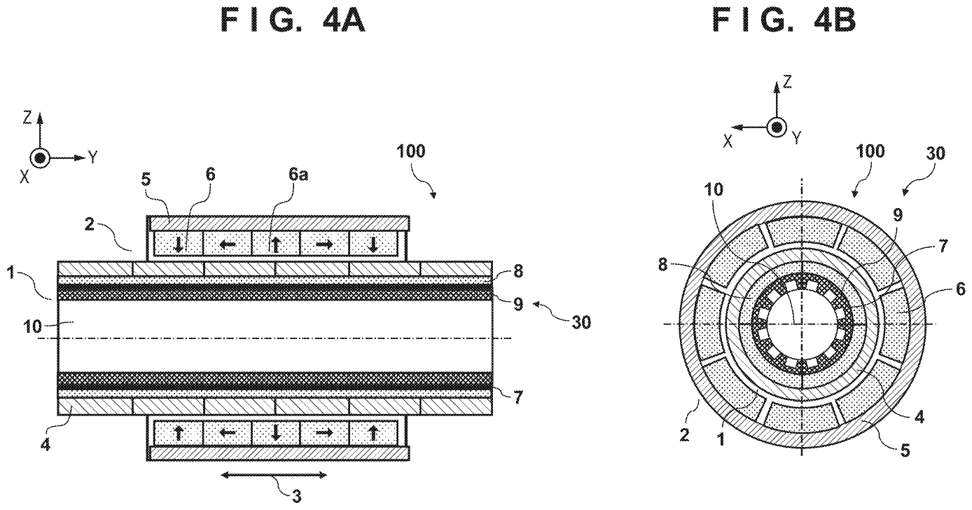

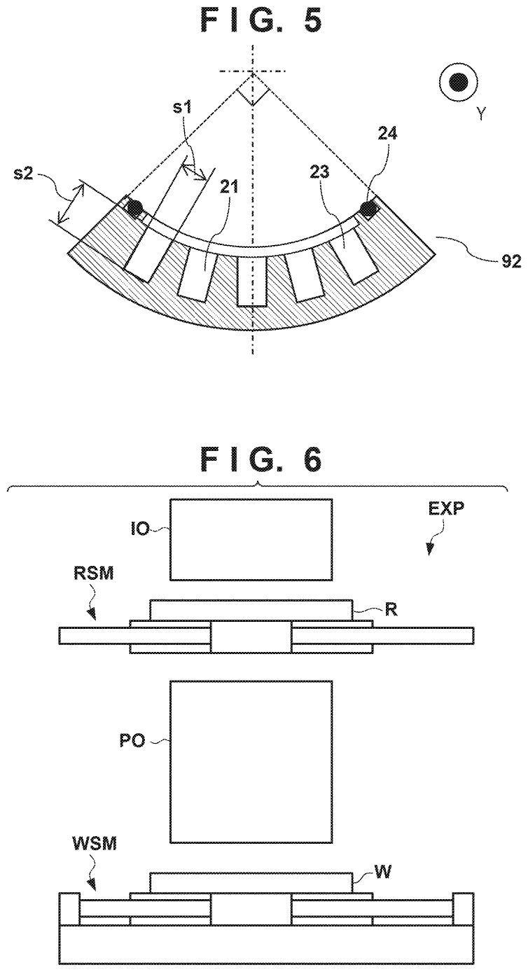

An actuator 100 according to the second embodiment will be described below with reference to FIGS. 4A, 4B, and 5. The second embodiment is a modification of the first embodiment, and matters not mentioned in the second embodiment can comply with the first embodiment. FIG. 4A is a sectional view showing a section parallel to the Y-Z plane of the actuator 100 according to the second embodiment, and FIG. 4B is a sectional view showing a section parallel to the X-Z plane of the actuator 100 according to the second embodiment. FIG. 5 is a sectional view (a sectional view orthogonal to the Y-axis) showing one component (a component 92 forming a first member 9 of a cooling unit 30) of the actuator 100.

In the second embodiment, a first element 1 as one of a mover and a stator can include an annular yoke 8, a plurality of annular coils 4 arrayed around the yoke 8 along the axial direction (Y-axis direction) of the yoke 8, and an annular cooling unit 30 arranged inside the yoke 8. In the second embodiment, a second element 2 as the other of the mover and the stator is arranged to surround the first element 1 in a section (a section parallel to the X-Z plane) orthogonal to a moving direction 3, and has an annular shape. The second element 2 can include a plurality of magnets 6 arrayed so that the magnetization direction changes along the moving direction 3, and an annular housing 5 that supports the plurality of magnets 6. The plurality of magnets 6 can be arrayed to form, for example, a Halbach array that generates a one-cycle substantially sine wave magnetic field. The plurality of magnets 6 can have an arc shape in a section orthogonal to the moving direction 3.

The first element 1 may include a support member 10 that supports the first member 9. In the first element 1, the plurality of coils 4 can be arranged at equal intervals along the moving direction 3. Each coil 4 can have an annular shape surrounding the support member 10. The plurality of coils 4 can be arranged to form coil lines of a plurality of phases (for example, two phases). The yoke 8 may be formed by a plurality of components each having an arc shape in a section (a section parallel to the X-Z plane) orthogonal to the moving direction 3. The cooling unit 30 can include the first member 9 having a plurality of grooves T extending along the axial direction (Y-axis direction) of the yoke 8, and the support member 10 or a facing member (not shown) serving as a second member arranged to face the plurality of grooves T. The first member 9 may be formed by a plurality of components 92 each having an arc shape in a section (a section parallel to the X-Z plane) orthogonal to the moving direction 3, as exemplified in FIG. 5. In the example shown in FIG. 5, the first member 9 is formed by the four divided components 92 but a division number may be two, three, or five or more.

FIG. 6 schematically shows the configuration of a lithography apparatus EXP that transfers a pattern of an original R to a substrate W. The lithography apparatus EXP is, for example, an exposure apparatus that transfers a pattern of a reticle as the original R to the substrate W. The lithography apparatus EXP can include, as an actuator for relatively moving the original R and the substrate W, the actuator 100 exemplarily described as the first or second embodiment. The lithography apparatus EXP can include, for example, an illumination optical system that illuminates the original R, an original stage mechanism RSM that drives the original R, a projection optical system PO, and a substrate stage mechanism WSM that drives the substrate W. The original stage mechanism RSM can incorporate the above-described actuator 100 as an actuator that drives an original stage holding the original R. The substrate stage mechanism WSM can incorporate the above-described actuator 100 as an actuator that drives a substrate stage holding the substrate W. The lithography apparatus EXP may be, for example, an imprint apparatus that transfers a pattern of a mold as the original R to a curable composition on the substrate W. In this case, the substrate stage mechanism WSM can incorporate the above-described actuator 100 as an actuator that drives the substrate stage holding the substrate W.

An article manufacturing method of manufacturing an article such as a semiconductor device, a display device, an optical device, or a MEMS using the lithography apparatus EXP will be described below. The article manufacturing method can include a transfer step of transferring a pattern of the original R to the substrate W using the lithography apparatus EXP, and a processing step of processing the substrate W having undergone the transfer step to obtain an article. The processing step can include, for example, a development step, an etching step, a dicing step, and a sealing step.

While the present disclosure has been described with reference to exemplary embodiments, it is to be understood that the present disclosure is not limited to the disclosed exemplary embodiments. The scope of the following claims is to be accorded the broadest interpretation so as to encompass all such modifications and equivalent structures and functions.

This application claims the benefit of Japanese Patent Application No. 2025-070798, filed Apr. 22, 2025, which is hereby incorporated by reference herein in its entirety.

What is claimed is:

1. An actuator comprising a mover and a stator, wherein
one of the mover and the stator includes a yoke, a plurality of coils arrayed around the yoke along an axial direction of the yoke, and a cooling unit arranged inside the yoke, and
the cooling unit includes a first member having a plurality of grooves extending along the axial direction of the yoke, and a second member arranged to face the plurality of grooves.

2. The actuator according to claim 1, wherein the first member is formed by a combination of a plurality of components, and some of the plurality of grooves are formed in each of the plurality of components.

3. The actuator according to claim 2, wherein each of the plurality of components has a plate shape.

4. The actuator according to claim 2, wherein each of the plurality of components has an arc-shaped section.

5. The actuator according to claim 2, wherein the second member includes a support member configured to support each of the plurality of components.

6. The actuator according to claim 5, wherein an O-ring is arranged between each of the plurality of components and the support member.

7. The actuator according to claim 5, wherein the first member and the support member are made of a material containing copper.

8. The actuator according to claim 5, wherein the first member and the support member are made of different metals, and a region where the first member and the support member contact a refrigerant is covered.

9. The actuator according to claim 8, wherein the first member is made of a material containing copper, and the support member is made of a material containing aluminum.

10. The actuator according to claim 2, wherein the second member includes a plurality of facing members respectively arranged to face the plurality of components forming the first member.

11. The actuator according to claim 10, wherein an O-ring is arranged between each of the plurality of components and a corresponding facing member among the plurality of facing members.

12. The actuator according to claim 10, further comprising a support member configured to support the plurality of facing members.

13. The actuator according to claim 10, wherein the first member and the plurality of facing members are made of a material containing copper.

14. The actuator according to claim 10, wherein the first member and the plurality facing members are made of different metals, and a region where the first member and the plurality of facing members contact a refrigerant is covered.

15. The actuator according to claim 1, wherein the first member is arranged outside the second member.

16. The actuator according to claim 1, wherein
the first member includes a plurality of fins arranged to define the plurality of grooves, and
an interval between the plurality of fins is smaller than a height of each the plurality of fins.

17. The actuator according to claim 16, wherein in a section orthogonal to the axi direction, the plurality of fins protrude toward an inside of the cooling unit.

18. The actuator according to claim 16, wherein the plurality of fins are arranged not to contact the second member.

19. A lithography apparatus for transferring a pattern of an original to a substrate, comprising:
an actuator including a mover and a stator and configured to relatively move the original and the substrate,
wherein one of the mover and the stator includes a yoke, a plurality of c arrayed around the yoke along an axial direction of the yoke, and a cooling unit arranged inside the yoke, and
wherein the cooling unit includes a first member having a plurality of grooves extending along the axial direction of the yoke, and a second member arranged to face the plurality of grooves.

20. An article manufacturing method comprising:
transferring a pattern of an original to a substrate using a lithography apparatus; and
processing the substrate having undergone the transferring to obtain an article,
wherein the lithography apparatus comprises an actuator including a mover and a stator and configured to relatively move the original and the substrate,
wherein one of the mover and the stator includes a yoke, a plurality of c arrayed around the yoke along an axial direction of the yoke, and a cooling unit arranged inside the yoke, and
wherein the cooling unit includes a first member having a plurality of grooves extending along the axial direction of the yoke, and a second member arranged to face the plurality of grooves.
